(19) United States
(12) Patent Application Publication
(10) Pub. No.: US 2025/0105825 A1
(43) Pub. Date: Mar. 27, 2025

(54) CIRCUIT FACILITATING OPTIMIZATION OF DATA FREQUENCY AND POWER CONSUMPTION AND A METHOD THEREOF

(71) Applicant: INDIAN INSTITUTE OF TECHNOLOGY ROPAR, Rupnagar (IN)

(72) Inventors: Puneet SINGH, Rupnagar (IN); Mayank Kumar SINGH, Rupnagar (IN); Mahendra SAKARE, Rupnagar (IN)

(21) Appl. No.: 18/393,261

(22) Filed: Dec. 21, 2023

(30) Foreign Application Priority Data
Sep. 21, 2023 (IN) 202311063391

(51) Int. Cl. H03K 3/012; H03K 3/037; H03K 17/687

(52) U.S. Cl. CPC H03K 3/012; H03K 3/037; H03K 17/6871

(57) ABSTRACT

A circuit and a method for optimizing data frequency and power consumption has a circuit comprising a flip flop which comprises a plurality of latches interconnected. Each latch of the plurality of latches comprises a plurality of pairs of transistors comprising a first plurality of transistors. The at least one transistor of the first plurality of transistors is connected to ground and at least another transistor of the first plurality of transistors is connected to power supply. Further, each latch of the plurality of latches comprises a second plurality of transistors and a third plurality of transistors. The third plurality of transistors is configured between the first plurality of transistors and the second plurality of transistors. Further, each transistor of the third plurality of transistors is connected to at least one of a transistor of the first plurality of transistors or a transistor of the second plurality of transistors.

### CROSS-REFERENCE TO RELATED APPLICATIONS AND PRIORITY

The present application claims benefit from Indian Patent Application No.: 202311063391 filed on 21 Sep. 2023 entirety of which is hereby incorporated by reference.

### TECHNICAL FIELD

The present disclosure, in general, relates to electronics and communication engineering. Particularly, to very-large-scale integration (VLSI) domain. More specifically, the present disclosure relates to a circuit and a method facilitating optimization of data frequency and power consumption.

### BACKGROUND

Demand for high-speed designs is rapidly increasing, driven by the need for various high-speed applications. One such application is Serializer Deserializer (SerDes), which comprises transmitters and receivers. In the realm of digital transceivers, where data rates continue to escalate, there is an urgent requirement for high-speed and low-power circuits. The performance of these circuits heavily relies on critical components such as a differential flip flop (D-FF), as it directly impacts speed, size, power consumption, reliability, and overall performance of a circuit. Additionally, the clocking network, responsible for synchronization, accounts for a substantial portion of the total power consumption, typically ranging from 20% to 40%.

The D-FF, being a fundamental building block in digital circuitry, finds applications in various domains, including phase detectors in phase-locked loops (PLL), clock and data recovery circuits (CDR), and pseudo-random binary sequence generators (PRBS).

The performance requirements of modern high-speed designs necessitate the development of innovative circuit architectures and optimization techniques. Achieving high speeds while minimizing power consumption is crucial to meet the growing demands of data-intensive applications. Designers strive to balance trade-offs between speed, power consumption, reliability, and area utilization. As a key component, the D-FF's design and characteristics significantly impact the overall performance of the circuit.

Further, the clocking network, responsible for synchronizing various components of the circuit, is a vital factor in achieving high-speed operation. Additionally, due to the traditional clocking network's significant contribution towards power consumption, there is a need to develop efficient clocking schemes that minimize power overhead without compromising synchronization accuracy. Traditionally, advanced clock gating techniques, frequency dividers, and clock distribution networks are among the strategies employed to optimize the power-performance trade-off.

Furthermore, conventionally, there are various architectures available for differential flip flops (D-FFs). Among the same, a non-precharge, two-phase-clocked Differential Cascode Voltage-Switch-Logic (DCVSL) based D-FF stands out due to its small transistor count and high speed. This particular flip-flop design incorporates only two clock transistors and eliminates stacking, resulting in a small clock input capacitance. The reduced capacitance minimizes power consumption in the clock driver buffers.

However, the aforesaid DCVSL circuits suffer from a drawback in the form of a large low-to-high propagation delay, limiting their overall speed and leading to asymmetrical output waveforms.

In view of the above, there should be a compact and cost-effective solution for enhancing the operating speed of the circuits may be by reducing rise and fall times. Specifically, the solution shall at least provide enhanced data capture, reduced propagation delay, and improved circuit reliability.

Therefore, the present disclosure is directed towards solving the above-identified and other problems existing in the art.

### SUMMARY

Before the present circuit and the method for optimizing data frequency and power consumption is described, it is to be understood that this application is not limited to the particular circuit, and methodologies described, as there can be multiple possible embodiments that are not expressly illustrated in the present disclosure. It is also to be understood that the terminology used in the description is to describe the particular implementations or versions or embodiments only, and is not intended to limit the scope of the present application.

This summary is provided to introduce aspects related to the circuit and the method for optimizing data frequency and power consumption. This summary is not intended to identify essential features of the claimed subject matter nor is it intended for use in determining or limiting the scope of the claimed subject matter.

In one implementation, a circuit for optimizing data frequency and power consumption is described. The circuit comprises a flip flop. The flip flop comprises a plurality of latches interconnected. Each latch of the plurality of latches comprises a plurality of pairs of transistors comprising a first plurality of transistors. The at least one transistor of the first plurality of transistors is connected to ground and at least another transistor of the first plurality of transistors is connected to power supply. Further, each latch of the plurality of latches comprises a second plurality of transistors and a third plurality of transistors. The third plurality of transistors is configured between the first plurality of transistors and the second plurality of transistors. Further, each transistor of the third plurality of transistors is connected to at least one of a transistor of the first plurality of transistors or a transistor of the second plurality of transistors.

In another implementation, a method for optimizing data frequency and power consumption using a circuit is described. The method for optimizing data frequency and power consumption comprises providing a flip flop comprising a plurality of latches, wherein the plurality of latches are interconnected, and wherein the plurality of latches comprises a first plurality of transistors, a second plurality of transistors, and a third plurality of transistors configured between the first plurality of transistors and the second plurality of transistors. Further, the method comprises connecting at least one transistor of the first plurality of transistors to ground. Further, the method comprises connecting at least another transistor of the first plurality of transistors to power supply. Further, the method comprises connecting each transistor of the third plurality of transistors to at least one of a transistor of the first plurality of transistors or a transistor of the second plurality of transistors.

### BRIEF DESCRIPTION OF DRAWINGS

The foregoing detailed description of embodiments is better understood when read in conjunction with the appended drawings. For the purpose of illustrating the present subject matter, an example of construction of the present subject matter is provided as figures; however, the invention is not limited to the specific circuit and the method disclosed in the document and the figures.

FIG. 1 illustrates a block diagram of a D-FF with a latch, in accordance with prior art;

FIG. 2 illustrates a circuit for optimizing data frequency and power consumption, in accordance with an embodiment of the present subject matter;

FIG. 3 illustrates a flow diagram of a method for optimizing data frequency and power consumption, in accordance with an embodiment of the present subject matter;

FIG. 4 illustrates operation of a latch when clock is disabled in a pre-charge mode, in accordance with an embodiment of the present subject matter;

FIG. 5 illustrates operation of the latch when the clock is enabled in a regenerative mode, in accordance with an embodiment of the present subject matter; and

FIG. 6 illustrates a comparison in timing between a conventional D-FF and a present D-FF, of the circuit (100), with different load capacitances at input data of 1 GHz frequency, in accordance with an embodiment of the present subject matter.

### DETAILED DESCRIPTION

Some embodiments of the present disclosure, illustrating all its features, will now be discussed in detail. The words “comprising”, “receiving”, “determining”, “assigning” and other forms thereof, are intended to be equivalent in meaning and be open ended in that an item or items following any one of these words is not meant to be an exhaustive listing of such item or items, or meant to be limited to only the listed item or items. It must also be noted that as used herein and in the appended claims, the singular forms “a”, “an” and “the” include plural references unless the context clearly dictates otherwise. Although any circuits and methods similar or equivalent to those described herein can be used in the practice or testing of embodiments of the present disclosure, the exemplary, circuits and methods for optimizing data frequency and power consumption are now described. The disclosed embodiments of the circuits and the methods for optimizing data frequency and power consumption are merely exemplary of the disclosure, which may be embodied in various forms.

Various modifications to the embodiment will be readily apparent to those skilled in the art, and the generic principles herein may be applied to other embodiments. However, one of ordinary skill in the art will readily recognize that the present disclosure for optimizing data frequency and power consumption is not intended to be limited to the embodiments illustrated but is to be accorded the widest scope consistent with the principles and features described herein.

Generally, in the realm of digital transceivers where data rates continue to escalate, there is an urgent requirement for high-speed and low-power circuits. The circuits incorporating a conventional D-FF impacts speed, size, power consumption, reliability, and overall performance of the circuits. Further, the circuits with the traditional clocking network, responsible for synchronization, accounts for the substantial portion of the total power consumption (typically ranging from 20% to 40%). Additionally, usage of the conventional D-FF in the circuits causes lack of noise immunity and susceptibility to common-mode noise.

The present subject matter overcomes the aforesaid problems. More specifically, problems related to optimization of data frequency and power consumption. The present circuit(s) and method(s) facilitates the optimization of data frequency and power consumption while addressing the aforesaid problems.

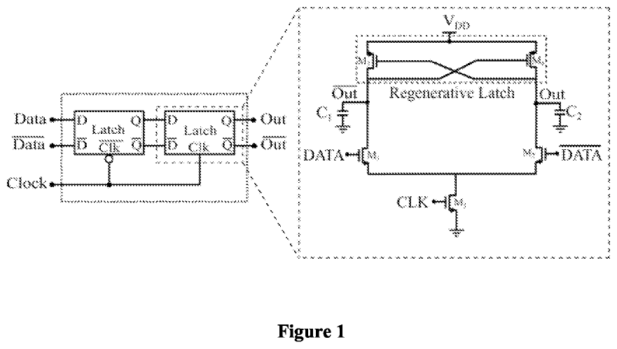

Referring now to the drawings, and more particularly to FIGS. 1 through 6, where similar reference characters denote corresponding features consistently throughout the figures, there are shown embodiments.

Numerous architectures for differential flip flops (D-FFs) have been explored in the art. One notable design is the non-precharge, two-phase-clocked Differential Cascode Voltage-Switch-Logic (DCVSL) based D flip-flop, as illustrated in FIG. 1. This flip-flop is particularly preferred due to its small transistor count and high speed. It incorporates only two clock transistors and avoids stacking, significantly reducing clock input capacitance. The smaller capacitance minimizes power consumption in the clock driver buffers.

However, DCVSL circuits suffer from a drawback in the form of a large low-to-high propagation delay, which limits their overall speed and leads to asymmetrical output waveforms.

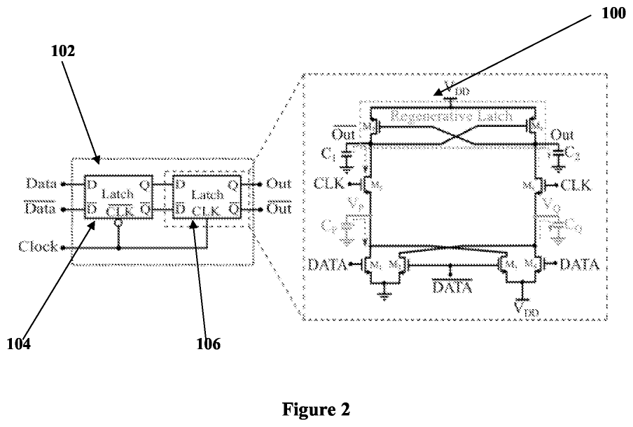

In accordance with an embodiment, referring to FIG. 2, a circuit (100) for optimizing data frequency and power consumption is shown. Specifically, FIG. 2 illustrates a block diagram of a D-FF and a latch of the circuit (100). The circuit (100) comprises a flip flop (102) that comprises a plurality of latches (104, 106) being interconnected. Each latch of the plurality of latches (104, 106) comprises a plurality of pairs of transistors comprising a first plurality of transistors (M1, M2, M3, M4), a second plurality of transistors (M7, M8), and a third plurality of transistors (M5, M6). Further, the circuit (100) provides that at least one transistor of the first plurality of transistors (M1, M2, M3, M4) is connected to ground. Further, the circuit (100) provides that at least another transistor of the first plurality of transistors (M1, M2, M3, M4) is connected to power supply V_{DD}. Further, the circuit (100) provides that the third plurality of transistors (M5, M6) is configured between the first plurality of transistors (M1, M2, M3, M4) and the second plurality of transistors (M7, M8). Further, the circuit (100) provides that each transistor of the third plurality of transistors (M5, M6) is connected to at least one of a transistor of the first plurality of transistors (M1, M2, M3, M4) or a transistor of the second plurality of transistors (M7, M8).

Further, the circuit (100) provides that a source terminal of the at least one transistor of the first plurality of transistors (M1, M2, M3, M4) is connected to the ground. Additionally, the circuit (100) provides that a source terminal of the at least another transistor of the first plurality of transistors (M1, M2, M3, M4) is connected to the power supply V_{DD}.

Moreover, the circuit (100) provides that the third plurality of transistors (M5, M6) are clocking transistors and are configured to control flow of data based on a clock signal.

Additionally, the circuit (100) provides that the first plurality of transistors (M1, M2, M3, M4) may comprise at least two N-channel metal-oxide semiconductor (NMOS) transistors. Further, the circuit (100) provides that the second plurality of transistors (M7, M8) may comprise at least two P-channel metal-oxide semiconductor (PMOS) transistors. Further, the circuit (100) provides that the third plurality of transistors (M5, M6) may include at least two transistors.

Furthermore, the circuit (100) provides that a pull-down network (PDN) of the circuit (100) comprises the at least two NMOS transistors. Moreover, the circuit (100) provides that a pull-up network (PUN) of the circuit (100) comprises the at least two PMOS transistors.

In addition, the circuit (100) provides that the second plurality of transistors (M7, M8) are configured in a cross-coupled manner and a source terminal of each of the second plurality of transistors (M7, M8) is connected to the power supply V_{DD}.

Furthermore, the circuit (100) provides that each of the first plurality of transistors (M1, M2, M3, M4), the second plurality of transistors (M7, M8), and the third plurality of transistors (M5, M6) are configured symmetrically.

Moreover, the circuit (100) provides that the flip flop (102) comprises a differential flip flop (D-FF).

In addition, the circuit (100) provides that each of the latch (104, 106) comprises a plurality of input nodes and a plurality of output nodes. The plurality of input nodes are configured to connect to gate terminals of the first plurality of transistors (M1, M2, M3, M4) such that the at least one transistor is configured to receive, via one gate terminal, input data and the at least another transistor is configured to receive, via another gate terminal, complement of the input data. The plurality of output nodes are configured between the second plurality of transistors (M7, M8) and the third plurality of transistors (M5, M6).

Furthermore, the circuit (100) provides that a first output node of the plurality of output nodes of each of the latch (104, 106) is configured to transmit output data. Moreover, a second output node of the plurality of output nodes is configured to transmit complement of the output data.

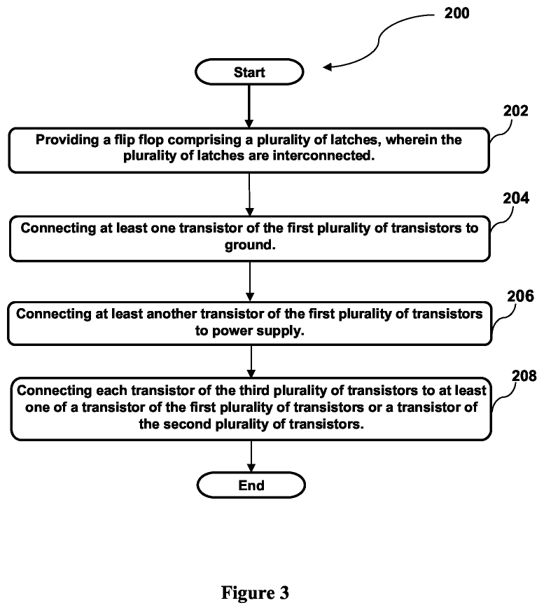

In another exemplary embodiment, referring to FIG. 3, a method (200) for optimizing data frequency and power consumption is shown. The method (200) may be executed using the circuit (100).

The order in which the method (200) for optimizing data frequency and power consumption is described is not intended to be construed as a limitation, and any number of the described method blocks may be combined/performed in any order, repetitively, iteratively or simultaneously to implement the method (200) or alternate methods. Additionally, individual blocks may be deleted from the method (200) without departing from the spirit and scope of the subject matter described herein. Further, the method (200) may be implemented in any suitable hardware. However, for ease of explanation, in the embodiments described below, the method (200) may be considered to be implemented using the above-described circuit (100).

At step 202, the method (200) provides a flip flop (102) comprising a plurality of latches (104, 106). Further, the method (200) provides that the plurality of latches (104, 106) are interconnected. Further, the method (200) provides that the plurality of latches (104, 106) comprises a first plurality of transistors (M1, M2, M3, M4), a second plurality of transistors (M7, M8), and a third plurality of transistors (M5, M6). Further, the method (200) provides that the third plurality of transistors (M5, M6) are configured between the first plurality of transistors (M1, M2, M3, M4) and the second plurality of transistors (M7, M8).

At step 204, the method (200) provides connecting at least one transistor of the first plurality of transistors (M1, M2, M3, M4) to ground.

At step 206, the method (200) provides connecting at least another transistor of the first plurality of transistors (M1, M2, M3, M4) to power supply V_{DD}.

At step 208, the method (200) provides connecting each transistor of the third plurality of transistors (M5, M6) to at least one of a transistor of the first plurality of transistors (M1, M2, M3, M4) or a transistor of the second plurality of transistors (M7, M8).

In another exemplary embodiment, the present invention proposes a novel low-power, compact, and symmetric differential D-FF architecture to overcome limitations of convention D-FF and provide a more compact and cost-effective solution. The main difference between the conventional DCVSL as shown in FIG. 1 and the present symmetrical differential D-latch architecture as shown in FIG. 2 lies in the connection of the source terminal of the input transistor to the positive supply and the symmetry of the architecture. Due to this symmetric design, the proposed architecture exhibits improved rise and fall time profiles. Notably, the rise and fall time of the proposed symmetrical differential D-latch is enhanced due to the connection of the supply voltage to one of the MOSFET's source terminals in the pull-down network (PDN). This connection enables the OUT terminal to transition to a high state earlier in the circuit's operation.

In the realm of computing and communication devices, there is a growing demand for low-power consumption and faster circuits. This drive for improved performance has led to Very Large Scale Integration (VLSI) technology scaling, resulting in higher transistor integration on a single chip. Consequently, the number of on-chip transistors has increased significantly. In the context of sequential circuits, latches and flip-flops serve as the primary memory cells. When a clock signal is applied, a latch becomes a flip-flop, transforming it into a master-slave configuration. The clock signal plays a critical role in synchronizing the input and command for storing data within the flip-flop. However, it is important to note that the output of the flip-flop takes some time to reflect the input change, which is commonly referred to as the propagation delay.

The proposed architecture for the D-FF follows a similar topology. It leverages a latch that is differential and symmetric in nature. This choice of a differential and symmetric latch in the design of the flip-flop offers several advantages. Differential signaling enables improved noise immunity, as it utilizes the voltage difference between two complementary signals to transmit information, enhancing the robustness of the circuit against external disturbances. Symmetry in the latch architecture ensures balanced and consistent operation, which helps mitigate potential timing issues and reduces process variations' impact. By incorporating a differential and symmetric latch in the proposed architecture, the D-FF aims to achieve enhanced performance characteristics. The use of a differential configuration allows for improved signal integrity, enabling reliable data storage and retrieval. Moreover, the latch's symmetric nature helps optimize the circuit's operation by providing balanced rise and fall times, ensuring efficient and accurate data transfer.

In another exemplary embodiment, a latch serves as the fundamental building block of the D-FF architecture. The proposed D latch, as depicted in FIG. 2 has been designed to operate at a higher frequency while minimizing power consumption, achieved through the utilization of only eight transistors. The Pull-down network within the latch consists of transistors M1, M2, M3, and M4, which form a differential switch. Transistors M5 and M6 are employed for the clock input in the proposed latch. On the other hand, the Pull-up network incorporates transistors M7 and M8, which are connected in a cross-coupled fashion. The drain of transistors M5 and M7 is connected to the OUT node, while the drain of transistors M6 and M8 is also connected to the OUT node. To establish the necessary connections, the drain of transistors M1 and M3 is linked to the source of transistor M5, and similarly, the drain of transistors M2 and M4 is connected to the source of transistor M5. Within the differential switch, the source of transistors M1 and M2 is connected to the ground, while the source of transistors M3 and M4 is connected to the V_{DD} supply.

The operation of the D-latch is as follows:
When the clock signal is at a low level, transistors M5 and M6 are turned off, isolating the input and output nodes from the latch's internal circuitry.
At this stage, the pass transistor logic comes into play, with each of the transistors (M1, M2, M3, and M4) forming a connection to facilitate the data transfer process.
The differential switch, composed of transistors M1 to M4, allows the data input to propagate to the OUT node based on the voltage levels applied to the input.
Upon receiving a rising edge of the clock signal, transistor M5 turns on, connecting the input to the latch's internal circuitry.
The output state of the latch remains latched until the next clock cycle occurs, preserving the stored data until a new input is received.

It is pertinent to mention that the D-latch works in two phases that are a pre-charge phase and a regenerative phase.

### The Pre-Charge Phase

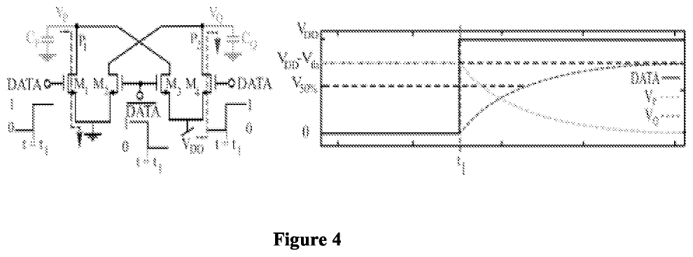

During the pre-charge phase of the D-latch, the clock signal transitions to a low level, resulting in the turning off of transistors M5 and M6, as depicted in FIG. 4. At a specific instant, denoted as t=t1, the DATA goes from low to high, and the transistors M2 and M3 are in the OFF state, while transistors M1 and M4 are turned ON. This configuration allows for the initiation of charging at node V_{Q} and discharging at node V_{P}, respectively, due to the presence of parasitic capacitance. Let us consider the initial conditions where the capacitor C_{P} at node V_{P} is assumed to have a potential of V_{DD}−Vₜₕ, and the capacitor C_{Q} at node V_{Q} is at a potential of 0. As the transitions and transistor M4 switch on, as shown in the waveform of FIG. 4, the capacitor C_{Q} begins to charge. The charging process continues until the voltage across C_{Q} reaches the level of V_{DD}−Vₜₕ. Simultaneously, transistor M1 turns on, allowing the discharge of capacitor C_{P}. This discharge causes the voltage at node V_{P} to decrease gradually and eventually reach 0 volts. During the pre-charge phase, it is important to note that transistor M4 operates in the saturation region, characterized by VDS (drain-to-source voltage) being greater than VGS (gate-to-source voltage) minus the threshold voltage (Vₜₕ). This ensures that transistor M4 functions optimally throughout the pre-charge cycle. The highest voltage that can be reached is as follows:

$${V}_{Q} ( t ) = ( {V}_{DD} - {V}_{th} ) \frac{{µ}_{n} {C}_{OX} \frac{{W}_{4}}{2 {C}_{q} {L}_{4}} ( {V}_{DD} - {V}_{th} ) t}{1 + {µ}_{n} {C}_{OX} \frac{{W}_{4}}{2 {C}_{q} {L}_{4}} ( {V}_{DD} - {V}_{th} ) t}$$

And so, the voltage at node V_{Q} can never get the full supply voltage level of V_{DD} during the logic “1” transfer. We can get the actual value of the maximum possible voltage V at node Q after considering the substrate bias effect for M4.

$${V}_{MAX} = {\vert {V}_{Q} \vert}_{t \to ∞} = {V}_{DD} - {V}_{th}$$

$${V}_{th} = {V}_{DD} - {V}_{th , 0} - γ ( \sqrt{\vert 2 {ϕ}_{F} \vert + {V}_{SB}} - \sqrt{\vert 2 {ϕ}_{F} \vert}$$

The pass transistor M1 operating in the linear region discharges the parasitic capacitor C_{P}, as follows:

$${V}_{P} ( t ) = \frac{2 ( {V}_{DD} - {V}_{th} )}{1 + exp ( {µ}_{n} {C}_{OX} \frac{{W}_{4}}{2 {C}_{q} {L}_{1}} ( {V}_{DD} - {V}_{th} ) t )}$$

Finally, the fall-time expression for the node voltage V_{P} can be obtained as

$${τ}_{fall} = \frac{2.74 {C}_{P}}{{µ}_{n} {C}_{OX} \frac{{W}_{1}}{{L}_{1}} ( {V}_{DD} - {V}_{TH} )}$$

### The Regenerative Phase

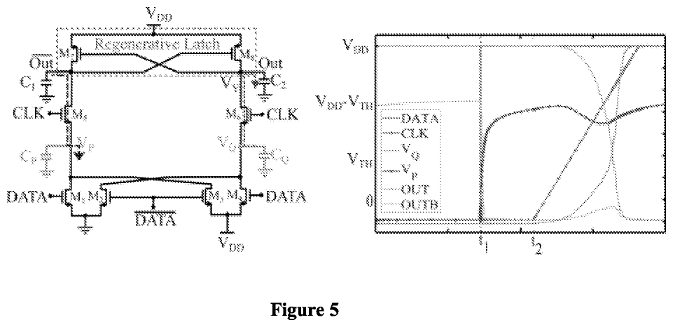

Let's consider the situation at time t=t1, where ‘OUT’ is at the logic ‘high’ level (V_{DD}), and ‘OUT’ is at the logic ‘low’ level (GND). During the regeneration phase, when the clock signal is enabled at t=t2, transistors M5 and M6 are turned on, as shown in FIG. 5. This activation allows the capacitors connected to the OUT and OUT nodes to start charging and discharging, respectively. The charging and discharging process follows the same equations as before. As the voltage at the OUT node gradually increases and exceeds the threshold voltage (Vₜₕ) of the PMOS transistor, transistor M7 is turned off. Similarly, as the voltage at the OUT node decreases and becomes lower than Vₜₕ, transistor M8 is turned on. The turning off of transistor M7 and the turning on of transistor M8 play a crucial role in the regenerative latch stage. As transistor M8 is turned on, the voltage at the OUT node rapidly rises towards V_{DD}. At the same time, turning off transistor M7 causes the voltage at the node to OUT rapidly decreases towards the ground. This cross-coupled configuration, which consists of transistors M7 and M8, is responsible for the regenerative behavior of the latch. The positive feedback created by the cross-coupling enables the regeneration of the analog signal into a rail-to-rail digital signal. It ensures that the voltage at the OUT node reaches the V_{DD} level and the voltage at the OUT node reaches the ground level, resulting in a clear distinction between logic ‘high’ and ‘low’ levels.

The time constant of the latch can be found by analyzing the circuit as

$${V}_{Out , \overline{Out}} ( t ) = {V}_{Out , \overline{Out}} ( 0 ) exp ( \frac{t}{{τ}_{reg}} )$$

τ_{reg} is the regenerative time constant which is given by

$${τ}_{reg} = \frac{{R}_{L} {C}_{L}}{( {g}_{m} {R}_{L} - 1 )}$$

where RL is the total load resistance, and CL is the total load capacitance at the output. Gm is the trans-conductance of the transistor M7 and M8. Finally, let's consider the two-stage master-slave flip-flop circuit depicted in FIG. 1. This circuit is constructed by cascading two D-latch circuits, resulting in enhanced stability and reliable data storage and transfer. In this circuit, the first stage, known as the master stage, receives the inverted clock signal, while the second stage, referred to as the slave stage, receives the regular clock signal. Consequently, the master stage is negative level-sensitive, as it responds to the falling edge of the clock, while the slave stage is positive level-sensitive, responding to the rising edge of the clock. When the clock signal is high, the master stage tracks the input value of D, while the slave stage holds the previously stored value from the previous clock cycle. This arrangement ensures that the output of the slave stage, denoted as Q, retains the previously stored value until the next clock transition.

During the transition from logic “1” to logic “0” of the clock, the master latch ceases to sample the input and stores the value of D at the falling edge of the clock. Simultaneously, the slave latch becomes transparent, allowing the stored value from the master stage to pass through and appear at the output of the slave stage, Q. It's worth noting that during this transition, the input D does not affect the result since the master stage is disconnected from the D input. As the clock changes again from logic “0” to “1,” the slave latch locks in the value from the output of the master latch, preserving it as the stored value. At the same time, the master stage resumes sampling the input D in preparation for the next clock cycle. Therefore, this circuit functions as a positive edge-triggered D flip-flop since it samples the input at the rising edge of the clock pulse. The positive edge triggers the transfer of data from the master stage to the slave stage, ensuring the stable and synchronized operation of the flip-flop.

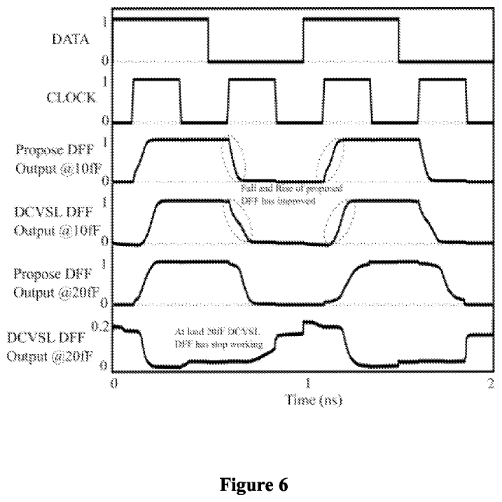

In another exemplary embodiment, referring to FIG. 6, a timing diagram comparing the performance of the DCVSL D-FF and the proposed symmetrical D-FF is presented. The comparison is conducted at a data input frequency of 1 GHz and with different load capacitances. The timing diagram illustrates the rise and fall times of the output signals for both D-FF architectures with varying load capacitances. It can be observed that the proposed symmetrical differential DFF exhibits improved rise and fall times compared to the DCVSL D-FF, particularly when loaded with 10 fF capacitance. Further, when the load capacitance increases to 20 fF, the DCVSL D-FF fails to operate properly, while the proposed symmetrical D-FF continues to function without any issues at this load condition.

To quantitatively analyze the rise and fall times, Table 1 presents the measured values for both D-FF architectures. The results highlight that with a 10 fF load capacitance, there is an increase in the rise and fall times compared to lower loads. However, even with this increase, the proposed symmetrical D-FF still outperforms the DCVSL D-FF in terms of propagation delay. The superior performance of the proposed D-FF is attributed to its innovative symmetrical architecture, which enhances signal integrity and enables efficient operation with larger load capacitances.

TABLE 1
Comparison of conventional DCVSL and proposed D-FF for
a load of 10 fF at the input of 1 GHz frequency.

| S. | | DCVSL based | Proposed | Improvement |
|---|---|---|---|---|
| No. | Parameters | DFF | DFF | (%) |
| 1 | Technology (nm) | 65 | 65 | — |
| 2 | Rise time (ps) | 66.37 | 53.68 | 19.12 |
| 3 | Fall time (ps) | 113.4 | 73.13 | 35.51 |
| 4 | Propagation delay (ps) | 129.05 | 47.31 | 63.34 |
| 5 | Power (uW) | 0.77 | 0.39 | 49.35 |
| 6 | PDP (Power delay | 99.36 | 18.45 | 81.43 |
| | product) | | | |

The foregoing description of the specific embodiments will so fully reveal the general nature of the embodiments herein that others can, by applying current knowledge, readily modify and/or adapt for various applications such specific embodiments without departing from the generic concept and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

1. A circuit for optimizing data frequency and power consumption, the circuit comprising:
a flip flop comprising:
a plurality of latches interconnected, wherein each latch of the plurality of latches comprises:
a plurality of pairs of transistors comprising a first plurality of transistors, wherein
at least one transistor of the first plurality of transistors is connected to ground, and wherein
at least another transistor of the first plurality of transistors is connected to a power supply;
a second plurality of transistors; and
a third plurality of transistors, wherein
the third plurality of transistors is configured between the first plurality of transistors and the second plurality of transistors, and wherein
each transistor of the third plurality of transistors is connected to at least one of a transistor of the first plurality of transistors or a transistor of the second plurality of transistors.

2. The circuit as claimed in claim 1, wherein a source terminal of the at least one transistor of the first plurality of transistors is connected to the ground, and wherein a source terminal of the at least another transistor of the first plurality of transistors is connected to the power supply.

3. The circuit as claimed in claim 1, wherein the third plurality of transistors are clocking transistors, and wherein the third plurality of transistors is configured to control flow of data based on a clock signal.

4. The circuit as claimed in claim 1, wherein the first plurality of transistors comprises at least two N-channel metal-oxide semiconductor (NMOS) transistors, wherein the second plurality of transistors comprises at least two P-channel metal-oxide semiconductor (PMOS) transistors, and wherein the third plurality of transistors comprises at least two transistors.

5. The circuit as claimed in claim 4, wherein a pull-down network (PDN) of the circuit comprises the at least two NMOS transistors, and wherein a pull-up network (PUN) of the circuit comprises the at least two PMOS transistors.

6. The circuit as claimed in claim 1, wherein the second plurality of transistors is configured in a cross-coupled manner, and wherein a source terminal of each of the second plurality of transistors is connected to the power supply.

7. The circuit as claimed in claim 1, wherein each of the first plurality of transistors, the second plurality of transistors, and the third plurality of transistors is configured symmetrically.

8. The circuit as claimed in claim 1, wherein the flip flop comprises a differential flip flop.

9. The circuit as claimed in claim 1, wherein each latch of the plurality of latches comprises:
a plurality of input nodes configured to connect to gate terminals of the first plurality of transistors such that the at least one transistor is configured to receive, via one gate terminal, input data and the at least another transistor is configured to receive, via another gate terminal, complement of the input data; and
a plurality of output nodes configured between the second plurality of transistors and the third plurality of transistors, wherein
a first output node of the plurality of output nodes is configured to transmit output data, and wherein
a second output node of the plurality of output nodes is configured to transmit complement of the output data.

10. A method for optimizing data frequency and power consumption using a circuit, the method comprising:
providing a flip flop comprising a plurality of latches, wherein the plurality of latches are interconnected, and wherein the plurality of latches comprises a first plurality of transistors, a second plurality of transistors, and a third plurality of transistors configured between the first plurality of transistors and the second plurality of transistors;
connecting at least one transistor of the first plurality of transistors to ground;
connecting at least another transistor of the first plurality of transistors to a power supply; and
connecting each transistor of the third plurality of transistors to at least one of a transistor of the first plurality of transistors or a transistor of the second plurality of transistors.
